(19) United States
(12) Patent Application Publication
(10) Pub. No.: US 2011/0300051 A1
(43) Pub. Date: Dec. 8, 2011

(54) GROUP-III NITRIDE MONOCRYSTAL WITH IMPROVED PURITY AND METHOD OF PRODUCING THE SAME

(75) Inventors: Derrick S. Kamber, Goleta, CA (US); Siddha Pimputkar, Goleta, CA (US); Makoto Saito, Ibaraki (JP); Steven P. Denbaars, Gotela, CA (US); James S. Speck, Goleta, CA (US); Shuji Nakamura, Santa Barbara, CA (US)

(73) Assignee: The Regents of the University of California, Oakland, CA (US)

(21) Appl. No.: 13/128,079

(22) PCT Filed: Nov. 4, 2009
(86) PCT No.: PCT/US09/63240

§ 371 Date: Aug. 18, 2011

Related U.S. Application Data
(60) Provisional application No. 61/112,555, filed on Nov. 7, 2008.

(51) Int. Cl. C01B 21/06; C30B 7/10

(52) U.S. Cl. 423/409; 117/70; 117/64

(57) ABSTRACT

A method to improve the crystal purity of a group-I11 nitride crystal grown in an ammonothermal growth system by removing any undesired material (i.e., impurities) from within the system prior to, in-between, or after the growth steps for the group-I11 nitride crystal. Impurities are removed from the ammonothermal growth system by first bringing the impurities into solution and then removing part or all of the solution from the growth system. The result is a high purity group-I11 nitride crystal grown in the ammonothermal growth system.

### CROSS REFERENCE TO RELATED APPLICATIONS

This application claims the benefit under 35 U.S.C. Section 119(e) of the following co-pending and commonly-assigned application:

U.S. Provisional Application Ser. No. 61/112,555, filed on Nov. 7, 2008, by Derrick S. Kamber, Siddha Pimputkar, Makoto Saito, Steven P. DenBaars, James S. Speck and Shuji Nakamura, entitled “GROUP-III NITRIDE MONOCRYSTAL WITH IMPROVED PURITY AND METHOD OF PRODUCING THE SAME,” attorney's docket number 30794.295-US-P1 (2009-282-1);

which application is incorporated by reference herein.

This application is related to the following co-pending and commonly-assigned U.S. patent applications:

U.S. Utility patent application Ser. No. 11/921,396, filed on Nov. 30, 2007, by Kenji Fujito, Tadao Hashimoto and Shuji Nakamura, entitled “METHOD FOR GROWING GROUP-III NITRIDE CRYSTALS IN SUPERCRITICAL AMMONIA USING AN AUTOCLAVE,” attorneys docket number 30794.129-US-WO (2005-339-2), which application claims the benefit under 35 U.S.C. Section 365(c) of PCT Utility Patent Application Serial No. US2005/024239, filed on Jul. 8, 2005, by Kenji Fujito, Tadao Hashimoto and Shuji Nakamura, entitled “METHOD FOR GROWING GROUP III-NITRIDE CRYSTALS IN SUPERCRITICAL AMMONIA USING AN AUTOCLAVE,” attorneys' docket number 30794.129-WO-01 (2005-339-1);

U.S. Utility patent application Ser. No. 11/784,339, filed on Apr. 6, 2007, by Tadao Hashimoto, Makoto Saito, and Shuji Nakamura, entitled “METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-U1 (2006-204), which application claims the benefit under 35 U.S.C. Section 119(e) of U.S. Provisional Patent Application Ser. No. 60/790,310, filed on Apr. 7, 2006, by Tadao Hashimoto, Makoto Saito, and Shuji Nakamura, entitled “A METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-P1 (2006-204);

U.S. Utility patent application Ser. No. 11/765,629, filed on Jun. 20, 2007, by Tadao Hashimoto, Hitoshi Sato and Shuji Nakamura, entitled “OPTO-ELECTRONIC AND ELECTRONIC DEVICES USING N-FACE OR M-PLANE GaN SUBSTRATE PREPARED WITH AMMONOTHERMAL GROWTH,” attorneys' docket number 30794.184-US-U1 (2006-666), which application claims the benefit under 35 U.S.C. Section 119(e) of U.S. Provisional Application Ser. No. 60/815,507, filed on Jun. 21, 2006, by Tadao Hashimoto, Hitoshi Sato, and Shuji Nakamura, entitled “OPTO-ELECTRONIC AND ELECTRONIC DEVICES USING N-FACE GaN SUBSTRATE PREPARED WITH AMMONOTHERMAL GROWTH,” attorneys' docket number 30794.184-US-P1 (2006-666);

U.S. Utility patent Ser. No. 12/234,244, filed on Sep. 19, 2008, by Tadao Hashimoto and Shuji Nakamura, entitled “GALLIUM NITRIDE BULK CRYSTALS AND THEIR GROWTH METHOD,” attorneys' docket number 30794.244-US-U1 (2007-809), which application claims the benefit under 35 U.S.C. Section 119(e) of U.S. Provisional Patent Application Ser. No. 60/973,662, filed on Sep. 19, 2007, by Tadao Hashimoto and Shuji Nakamura, entitled “GALLIUM NITRIDE BULK CRYSTALS AND THEIR GROWTH METHOD,” attorneys' docket number 30794.244-US-P1 (2007-809-1);

U.S. Utility patent application Ser. No. 11/977,661, filed on Oct. 25, 2007, by Tadao Hashimoto, entitled “METHOD FOR GROWING GROUP III-NITRIDE CRYSTALS IN A MIXTURE OF SUPERCRITICAL AMMONIA AND NITROGEN, AND GROUP III-NITRIDE CRYSTALS GROWN THEREBY,” attorneys' docket number 30794.253-US-U1 (2007-774-2), which application claims the benefit under 35 U.S.C. Section 119(e) of U.S. Provisional Application Ser. No. 60/854,567, filed on Oct. 25, 2006, by Tadao Hashimoto, entitled “METHOD FOR GROWING GROUP-III NITRIDE CRYSTALS IN MIXTURE OF SUPERCRITICAL AMMONIA AND NITROGEN AND GROUP-III NITRIDE CRYSTALS,” attorneys' docket number 30794.253-US-P1 (2007-774);

U.S. Utility patent application Ser. No. ______, filed on same date herewith, by Siddha Pimputkar, Derrick S. Kamber, Makoto Saito, Steven P. DenBaars, James S. Speck and Shuji Nakamura, entitled “GROUP-III NITRIDE MONOCRYSTAL WITH IMPROVED CRYSTAL QUALITY GROWN ON AN ETCHED-BACK SEED CRYSTAL AND METHOD OF PRODUCING THE SAME,” attorneys' docket number 30794.288-US-U1 (2009-154-2), which application claims the benefit under 35 U.S.C. Section 119(e) of U.S. Provisional Application Ser. No. 61/111,644, filed on Nov. 5, 2008, by Siddha Pimputkar, Derrick S. Kamber, Makoto Saito, Steven P. DenBaars, James S. Speck and Shuji Nakamura, entitled “GROUP-III NITRIDE MONOCRYSTAL WITH IMPROVED CRYSTAL QUALITY GROWN ON AN ETCHED-BACK SEED CRYSTAL AND METHOD OF PRODUCING THE SAME,” attorney's docket number 30794.288-US-P1 (2009-154-1);

P.C.T. International Patent Application Serial No. PCT/US09/______, filed on same date herewith, by Siddha Pimputkar, Derrick S. Kamber, James S. Speck and Shuji Nakamura, entitled “REACTOR DESIGNS FOR USE IN AMMONOTHERMAL GROWTH OF GROUP-III NITRIDE CRYSTALS,” attorneys' docket number 30794.296-WO-U1 (2009-283/285-2), which application claims the benefit under 35 U.S.C. Section 119(e) of U.S. Provisional Application Ser. No. 61/112,560, filed on Nov. 7, 2008, by Siddha Pimputkar, Derrick S. Kamber, James S. Speck and Shuji Nakamura, entitled “REACTOR DESIGNS FOR USE IN AMMONOTHERMAL GROWTH OF GROUP-III NITRIDE CRYSTALS,” attorney's docket number 30794.296-US-P1 (2009-283/285-1);

P.C.T. International Patent Application Serial No. PCT/US09/______, filed on same date herewith, by Siddha Pimputkar, Derrick S. Kamber, James S. Speck and Shuji Nakamura, entitled “NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS,” attorneys' docket number 30794.297-WO-U1 (2009-284-2), which application claims the benefit under 35 U.S.C. Section 119(e) of U.S. Provisional Application Ser. No. 61/112,552, filed on Nov. 7, 2008, by Siddha Pimputkar, Derrick S. Kamber, James S. Speck and Shuji Nakamura, entitled “NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS,” attorney's docket number 30794.297-US-P1 (2009-284-1);

P.C.T. International Patent Application Serial No. PCT/US09/______, filed on same date herewith, by Siddha Pimputkar, Derrick S. Kamber, James S. Speck and Shuji Nakamura, entitled “ADDITION OF HYDROGEN AND/OR NITROGEN CONTAINING COMPOUNDS TO THE NITROGEN-CONTAINING SOLVENT USED DURING THE AMMONOTHERMAL GROWTH OF GROUP-III NITRIDE CRYSTALS,” attorneys' docket number 30794.298-WO-U1 (2009-286-2), which application claims the benefit under 35 U.S.C. Section 119(e) of U.S. Provisional Application Ser. No. 61/112,558, filed on Nov. 7, 2008, by Siddha Pimputkar, Derrick S. Kamber, James S. Speck and Shuji Nakamura, entitled “ADDITION OF HYDROGEN AND/OR NITROGEN CONTAINING COMPOUNDS TO THE NITROGEN-CONTAINING SOLVENT USED DURING THE AMMONOTHERMAL GROWTH OF GROUP-III NITRIDE CRYSTALS TO OFFSET THE DECOMPOSITION OF THE NITROGEN-CONTAINING SOLVENT AND/OR MASS LOSS DUE TO DIFFUSION OF HYDROGEN OUT OF THE CLOSED VESSEL,” attorney's docket number 30794.298-US-P1 (2009-286-1);

P.C.T. International Patent Application Serial No. PCT/US09/______, filed on same date herewith, by Siddha Pimputkar, Derrick S. Kamber, James S. Speck and Shuji Nakamura, entitled “CONTROLLING RELATIVE GROWTH RATES OF DIFFERENT EXPOSED CRYSTALLOGRAPHIC FACETS OF A GROUP-III NITRIDE CRYSTAL DURING THE AMMONOTHERMAL GROWTH OF A GROUP-III NITRIDE CRYSTAL,” attorneys' docket number 30794.299-WO-U1 (2009-287-2), which application claims the benefit under 35 U.S.C. Section 119(e) of U.S. Provisional Application Ser. No. 61/112,545, filed on Nov. 7, 2008, by Siddha Pimputkar, Derrick S. Kamber, James S. Speck and Shuji Nakamura, entitled “CONTROLLING RELATIVE GROWTH RATES OF DIFFERENT EXPOSED CRYSTALLOGRAPHIC FACETS OF A GROUP-III NITRIDE CRYSTAL DURING THE AMMONOTHERMAL GROWTH OF A GROUP-III NITRIDE CRYSTAL,” attorney's docket number 30794.299-US-P1 (2009-287-1); and

P.C.T. International Patent Application Serial No. PCT/US09/______, filed on same date herewith, by Siddha Pimputkar, Derrick S. Kamber, James S. Speck and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorneys' docket number 30794.300-WO-U1 (2009-288-2), which application claims the benefit under 35 U.S.C. Section 119(e) of U.S. Provisional Application Ser. No. 61/112,550, filed on Nov. 7, 2008, by Siddha Pimputkar, Derrick S. Kamber, James S. Speck and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorney's docket number 30794.300-US-P1 (2009-288-1); all of which applications are incorporated by reference herein.

### BACKGROUND OF THE INVENTION

1. Field of the Invention

This invention relates to ammonothermal growth of group-III nitrides.

2. Description of the Related Art

Ammonothermal growth of group-III nitrides, for example, GaN, involves placing, within a reactor vessel, group-III containing source materials, group-III nitride seed crystals, and a nitrogen-containing solvent, such as ammonia, sealing the vessel and heating the vessel to conditions such that the vessel is at elevated temperatures (between 23° C. and 1000° C.) and high pressures (between 1 atm and, for example, 30,000 atm). Under these temperatures and pressures, the nitrogen-containing solvent may become a supercritical fluid which normally exhibits enhanced solubility of the group-III containing materials into solution. The solubility of the group-III containing materials into the nitrogen-containing solvent is dependent on the temperature, pressure and density of the solvent, among other things.

The purity of group-III nitride crystals grown in a supercritical nitrogen-containing solvent is of major importance. Impurities are introduced into the growth environment from the group-III containing sources (such as Ga or GaN), seed crystals (such as GaN substrates grown by hydride vapor phase epitaxy (HVPE) or ammonothermal methods), mineralizers (which enhance the solubility of the group-III containing sources into the solvent), the vessel walls, and from the surfaces of items which are placed in the growth environment (such as baffle plates, seed racks and source baskets). These impurities may then be incorporated into the growing group-III nitride crystal, resulting in a deterioration in crystal purity, crystal quality, and/or crystal properties.

Thus, there exists a need in the art to improve the purity of a group-III nitride crystal grown in a supercritical nitrogen-containing solvent by removing impurities from the growth system. The present invention satisfies this need.

### SUMMARY OF THE INVENTION

To overcome the limitations in the prior art described above, and to overcome other limitations that will become apparent upon reading and understanding the present invention, the present invention discloses a method to improve the crystal purity of a group-III nitride crystal grown in an ammonothermal growth system by removing undesired material (i.e., impurities) from the system prior to, in-between, or after the growth steps for the group-III nitride crystal. Specifically, the present invention discloses a method for removing impurities from the ammonothermal growth system by first bringing the impurities into solution and then removing part or all of the solution from the growth system. The result is a high purity group-III nitride crystal grown in the ammonothermal growth system.

### BRIEF DESCRIPTION OF THE DRAWINGS

Referring now to the drawings in which like reference numbers represent corresponding parts throughout:

FIG. 1 is a schematic of a high-pressure vessel according to an embodiment of the present invention.

FIG. 2 is a flowchart illustrating the method according to an embodiment of the present invention.

### DETAILED DESCRIPTION OF THE INVENTION

In the following description of the preferred embodiment, reference is made to a specific embodiment in which the invention may be practiced. It is to be understood that other embodiments may be utilized and structural changes may be made without departing from the scope of the present invention.

Technical Description

The purity of group-III nitride crystals grown in a supercritical nitrogen-containing solvent is of major importance. Impurities are introduced into the growth environment from the group-III containing sources (such as Ga or GaN), seed crystals (such as GaN substrates grown by hydride vapor phase epitaxy (HVPE) or ammonothermal methods), mineralizers (which enhance the solubility of the group-III containing sources into the solvent), the vessel walls, and from the surfaces of items which are placed in the growth environment (such as baffle plates, seed racks and source baskets). These impurities may then be incorporated into the growing group-III nitride crystal, resulting in a deterioration in crystal purity, crystal quality, and/or crystal properties. To avoid these problems, the present invention discloses a method to remove impurities from the growth system.

The method involves placing, among other things, one or more group-III containing sources, seed crystals, and/or mineralizers into the growth system, which comprises a vessel that contains at least one solvent. This vessel is then sealed and heated to one or more temperatures. The ability of the solvent to dissolve material into solution varies with temperature, so raising the temperature of the vessel, and hence the solvent within the vessel, results in either an increase or decrease in solubility. The temperature is only one parameter that affects the ability of the solvent to dissolve material from within the vessel into solution. Other parameters include, but are not limited to, pressure, and density of the solvent. The dissolution of material from the group-III containing sources, seed crystals, mineralizers and/or other surfaces within the vessel by utilizing any number of solvents, which are at any number of pressures, temperatures and densities, is an integral part of this invention.

The solvent used for this particular dissolution and purifying step, which may be part of a multi-step process of ultimately obtaining a group-III nitride crystal grown in nitrogen-containing supercritical solvent, may, but does not have to be, a nitrogen-containing compound. The solvent may and should be selected in such a fashion as to maximize the solubility of the desired impurity and/or material which one desires to dissolve. Hence, if multiple impurities need to be removed from the vessel, and no suitable solvent is found that would simultaneously dissolve all the desired impurities in the quantity and fashion that is desired, this invention envisions repeating the dissolution and purifying step multiple times while using the same, similar, or different solvent materials in sequence to dissolve the various materials and/or compounds sequentially. Similarly, the present invention incorporates the use of one or more mineralizers within the solvent to enhance the solubility of the desired impurity and/or material, and these mineralizers may be added to the vessel one or more times during the one or more dissolution and purifying step steps while using the same, similar, or different solvent materials.

One possible example of a solvent that could be beneficial to use during the dissolution and purifying step when one desires to dissolve group-III compounds and/or elements from the exposed surfaces would be to use a nitrogen-containing solvent, possibly, though not necessarily, containing additional mineralizers to enhance the solubility of the group-III compound(s) and/or elements. If one would though, for example, wish to remove oxygen from the system, it may be beneficial to use a solvent that contains one or more boron-containing compounds. It is further possible to mix multiple solvents, containing any number of elements and/or compounds from the periodic table of elements, to enhance the ability of the solvent to absorb a larger variety of materials and/or compounds more efficiently and effectively. These elements and/or compounds are commonly referred to as mineralizers within the art.

After filling the vessel with the necessary and desired materials, and including a certain quantity of solvent selected based on the desired material(s) and/or compound(s) one wishes to dissolve into solution, the vessel may be heated to one or more temperatures in one or more zones, where the temperatures are typically between 22° C. and 1000° C. but may be higher. Depending on the quantity of solvent filled into the vessel, the equilibrium partial pressures and densities of the solvent may vary. Due to this, the solvents may present themselves in any possible phase, for example, the liquid, solid, gas and/or supercritical state.

The present invention further includes any possible scheme of increasing, decreasing, holding and varying the ability of the solvent to dissolve and/or precipitate out material. It may be beneficial to vary the temperature, pressure and/or density of the solvent(s) within the vessel at any point in time during the dissolution and purifying step. The temperature may, for example, be varied by modifying the temperature of the vessel using specific heating and/or cooling rate(s). The pressure and/or density may be changed, for example, by varying the temperature and/or removing material from the vessel, for example by venting some of the solvent out of the vessel. By changing any one or more of the parameters, which ultimately may influence the solubility of one or more materials within the vessel, it may be possible to optimize the dissolution and purifying step. Therefore, any possible pattern of variations in temperature, pressure, density and hence solubility of one or more materials and/or compounds from within the vessel into the solvent during the dissolution and purifying step is part of the present invention.

After a certain period of time, which may be, for example, any period between 1 min and 60 days, all or part of the solvent containing the dissolved material, and/or the dissolved material including, but not limited to, contaminants and impurities, may then be removed from the vessel. This removal from the vessel may be accomplished by, for example, venting the vessel. Furthermore, this removal may be performed at any temperature of the vessel and at any temperature, pressure or density of the solvent(s), but is preferentially performed at elevated temperatures between 100° C. and 1000° C. and pressures between 1 atm and 30000 atm.

After some or all of the solvent removal, the vessel may then be reloaded with solvent(s). If one or more dissolution and purifying steps are desired, the solvent will be selected in such a fashion to improve on the purity of the environment within the vessel by choosing one or more appropriate solvents. One or more mineralizers may also be added to the vessel to increase the solubility of the desired material into the solution. The vessel may then be subjected to another cycle comprising another dissolution and purifying step with a specific amount of solvent, involving heating the vessel to one or more temperatures in one or more zones and subsequently, after performing any number of variations in pressure, temperature and density of the solvent, removing all or part of the solvent containing dissolved material from the vessel. If, alternatively, one wishes to perform a different operational step, for example, the growth of a high purity group-III nitride crystal, the vessel is filled with a solvent that is appropriate and optimized for the desired growth conditions.

While it may be possible to perform the dissolution and purifying step(s) outlined in this invention immediately before the growth step, it does not have to be done in this sequence. The dissolution and purifying step(s) may be performed at any time and/or in between any number of steps during a multi-step operation which ultimately desires to grow a high purity group-III nitride crystal. This may, therefore, include performing the dissolution and purifying step in between other unspecified operations, and/or before the growth of a high purity group-III nitride crystal, and/or after the growth of the high purity group-III nitride crystal. The present invention includes the use of one or more cycles comprising one or more dissolution and purifying steps prior to, during, or after the growth of the group-III nitride crystal.

An example of using the dissolution and purifying step after and/or in-between a growth of the group-III nitride crystal, would be when one desires to grow a group-III nitride crystal with various materials/dopants included at different times during growth, resulting in a group-III nitride crystal with areas/layers of varying concentrations of different materials/dopants. For example, if one wishes to grow a group-III nitride p-n junction using the ammonothermal method, it is necessary to initially grow the group-III nitride crystal which, for example, is rich in a material/dopant, for example Mg, which, when incorporated into the group-III nitride crystal, binds one of the free electrons tightly to the dopant used and hence makes it a p-type material. After growing the p-type material, one may wish to grow an n-type material, which would involve growing a group-III nitride crystal which is rich in a different material, for example, Si, which, when incorporated into the group-III nitride crystal, donates electrons to the conduction band of the material, hence providing additional free electrons to the semiconductor and making the grown group-III nitride crystal material an n-type material. In-between the two steps of growing the p-type material, by virtue of including, for example, Mg atoms and/or compounds into the nitrogen-containing supercritical solvent during growth and the n-type material, by virtue of including, for example, Si atoms and/or compounds into the nitrogen-containing supercritical solvent during growth, it may be desirable to remove any remaining Mg atoms and/or compounds from within the vessel. This may be achieved by performing a dissolution and purifying step as outlined in this invention after growing, for example, the p-type group-III nitride crystal but before growing, for example, the n-type group-III nitride crystal with solvents that are able to dissolve Mg into solution and hence purify the system of any remaining Mg material which may not be beneficial during the growth of the n-type group-III nitride crystal.

The present invention also provides a high-purity group-III nitride crystal grown in a supercritical nitrogen-containing solvent in a growth system possessing reduced impurities due to subjecting the growth system to one or more removals of impurities, materials and/or compounds from the growth system, as described above.

Apparatus Description

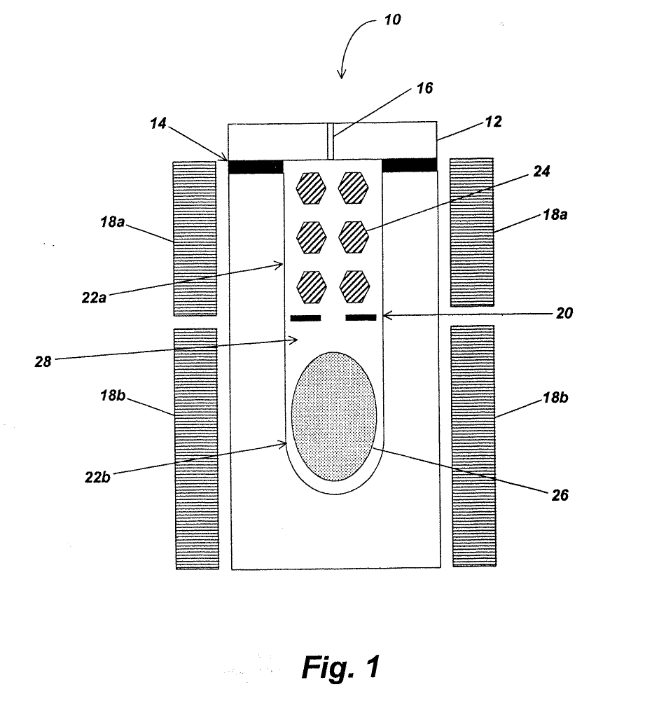

FIG. 1 is a schematic of an ammonothermal growth system comprising a high-pressure reaction vessel 10 according to one embodiment of the present invention. The vessel, which is an autoclave, may include a lid 12, gasket 14, inlet and outlet port 16, and external heaters/coolers 18a and 18b. A baffle plate 20 divides the interior of the vessel 10 into two zones 22a and 22b, wherein the zones 22a and 22b are separately heated and/or cooled by the external heaters/coolers 18a and 18b, respectively. An upper zone 22a may contain one or more group-III nitride seed crystals 24 and a lower zone 22b may contain one or more group-III containing source materials 26, although these positions may be reversed in other embodiments. Both the group-III nitride seed crystals 24 and group-III containing source materials 26 may be contained within baskets or other containment devices, which are typically comprised of a Ni—Cr alloy. The vessel 10 and lid 12, as well as other components, may also be made of a Ni—Cr based alloy. Finally, the interior of the vessel 10 is filled with a nitrogen-containing solvent 28 to accomplish the ammonothermal growth.

### Process Description

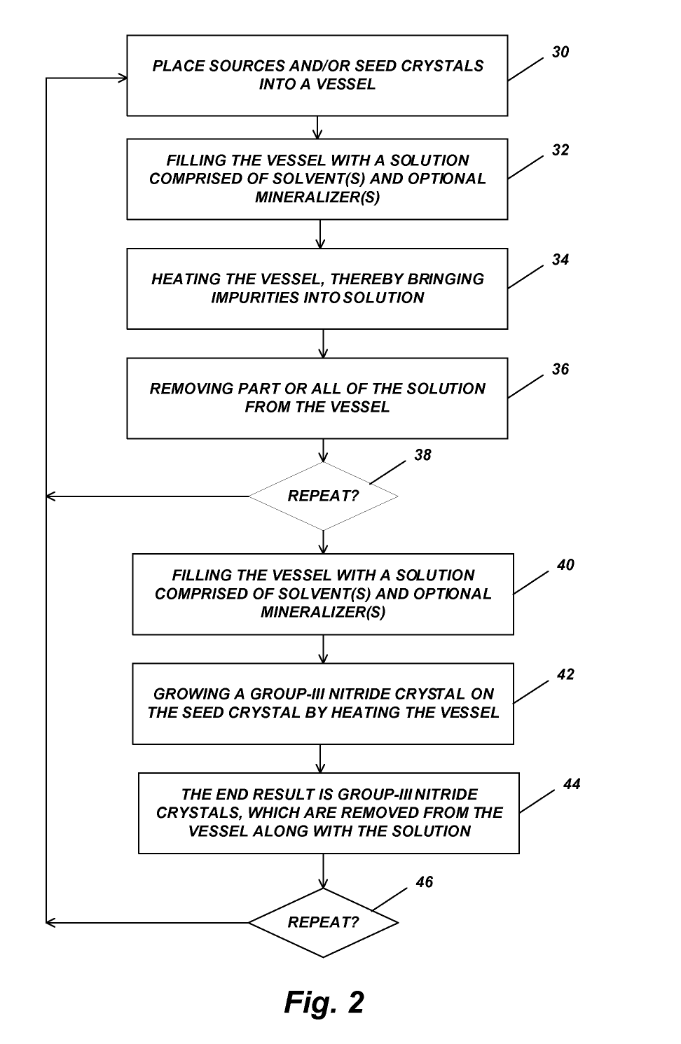

FIG. 2 is a flow chart illustrating a method for obtaining or growing a group-III nitride crystal according to one embodiment of the present invention.

Block 30 represents placing one or more group-III containing sources and/or one or more seed crystals into the vessel, wherein the group-III containing sources are placed in a source zone and the seed crystals are placed in a seed crystal zone. The group-III containing sources may comprise a group-III containing compound, a group-III element in pure elemental form, or a mixture thereof, i.e., a group-III element, a group-III nitride monocrystal, a group-III nitride polycrystal, a group-III nitride powder, group-III nitride granules, or other group-III containing compound; and the seed crystals may comprise a group-III containing single crystal.

Block 32 represents filling the vessel with a solution comprised of one or more solvents and, optionally, one or more mineralizers, and then sealing the vessel. The solvents may comprise a nitrogen-containing solvent, such as ammonia or one or more of its derivatives, which may be processed to become supercritical. The mineralizers increase the solubility of the group-III containing sources in the solvents as compared to the solvents without the mineralizers. Further, mineralizers may be placed into the vessel to enhance the solubility of the impurities in the solvent.

Block 34 represents heating the vessel, thereby bringing the impurities into the solution within the vessel. As noted previously, the impurities may have been introduced into the vessel, for example, from the group-III containing sources, seed crystals, mineralizers, the vessel walls, or from surfaces of items placed in the vessel.

Block 36 represents removing part or all of the solution from the vessel, thereby removing the impurities from the vessel.

As noted previously, Blocks 30, 32, 34 and 36 may also include the varying of process parameters, such as solvent's temperature, pressure, density and solubility, for the purposes of increasing, decreasing, holding and varying the solvent's ability to dissolve or precipitate out the impurities.

Preferably, the solution, which comprises the solvent and any additional mineralizers if present, is selected to maximize solubility of the impurities, and the same, similar, or different solvents may be used in sequence by repeating Blocks 30, 32, 34 and 36, as indicated at Block 38, to dissolve the same, similar, or different impurities sequentially. Specifically, Blocks 30, 32, 34 and 36, as indicated at Block 38, may be repeated as necessary, by reloading the vessel with a new solvent after the previous solvent has been removed from the vessel, and then repeating the steps involved. For example, the solvent may comprise a nitrogen-containing solvent to dissolve impurities comprised of group-III containing materials, or the solvent may comprise a boron-containing solvent to dissolve impurities comprised of oxygen-containing materials.

Thus, Blocks 30, 32, 34, 36, and 38 together comprise a method for improving the purity of the group-III nitride crystal grown in the supercritical nitrogen-containing solvent by removing impurities from the ammonothermal growth system, namely the vessel.

Block 40 represents filling the vessel with a solution comprised of one or more solvents and, optionally, one or more mineralizers, and then sealing the vessel.

Block 42 represents growing one or more group-III nitride crystals on the seed crystals by heating the vessel to dissolve the group-III containing source into the solution and then transporting the solution to the seed crystals in order to grow the group-III nitride crystals on one or more surfaces of the seed crystals.

Block 44 represents the end result of the growth, namely the group-III nitride crystals. This Block may also represent removing group-III nitride crystals from the vessel, as well as removing part or all of the solution from the vessel. Finally, Block 46 indicates that the entire sequence of Blocks 30, 32, 34, 36, 38, 40, 42, 44 and 46, may be repeated as desired. In addition, it is anticipated that a different sequence of these steps may be performed as well. Thus, while the dissolution and purifying steps may be performed before the growth steps, the dissolution and purifying steps may also be performed after the growth steps or between subsequent growth steps.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for improving a purity of a group-III nitride crystal grown in an ammonothermal growth system, comprising:
(a) bringing one or more impurities into solution within the growth system; and
(b) removing part or all of the solution from the growth system, to remove some or all of the impurities from the growth system.

2. The method of claim 1, wherein the impurities are introduced into the growth system from one or more group-III containing sources, one or more seed crystals, one or more mineralizers, one or more vessel walls, or from one or more items placed in the growth system.

3. The method of claim 2, wherein the growth system includes a vessel and the method further comprises:
selectively placing the group-III containing sources and the seed crystals into the vessel;
placing one or more solvents, into the vessel;
sealing the vessel; and
heating the vessel to one or more temperatures to dissolve some or all of the impurities into the solvent, thereby creating the solution, wherein solubility of the impurities in the solvent varies with the solvent's temperature, pressure and density.

4. The method of claim 3, wherein the solvent is selected to maximize solubility of the impurities.

5. The method of claim 3, wherein the same, similar, or different solvents are used in sequence to dissolve the same, similar, or different impurities sequentially.

6. The method of claim 3, wherein the solvent comprises a nitrogen-containing solvent to dissolve impurities comprised of group-III containing materials.

7. The method of claim 3, wherein the solvent comprises a boron-containing solvent to dissolve impurities comprised of oxygen-containing materials.

8. The method of claim 3, further comprising placing mineralizers into the vessel to enhance the solubility of the impurities in the solvent.

9. The method of claim 3, further comprising increasing, decreasing, holding or varying the solution's ability to dissolve or precipitate out the impurities.

10. The method of claim 1, wherein part or all of the solution is removed at a temperature above 132° C.

11. The method of claim 1, further comprising reloading the growth system after part or all of the solution has been removed from the growth system and repeating steps (a) and (b).

12. The method of claim 1, further comprising performing one or more growth steps before or after performing steps (a) and (b).

13. The method of claim 12, further comprising:
performing a first growth step with a first material before performing steps (a) and (b) to remove any remaining portions of the first material from the growth system; and
performing a second growth step with a second material before performing steps (a) and (b) to remove any remaining portions of the second material from the growth system.

14. A group-III nitride crystal grown by the method of claim 12.

15. A group-III nitride substrate created from the group-III nitride crystal of claim 14.

16. A device created using the group-III nitride substrate of claim 15.

17. A method of purifying group-III containing source materials in a supercritical nitrogen-containing solvent, comprising:
(a) placing at least one group-III containing source and at least one nitrogen-containing solvent in a vessel;
(b) bringing one or more impurities into solution within the vessel; and
(c) removing part or all of the solution from the vessel to remove some or all of the impurities from the growth system.

18. The method of claim 17, further comprising placing one or more mineralizers in the vessel.

19. The method of claim 17, wherein part of all of the solution is removed at a temperature above 132° C.

20. A group-III nitride crystal grown using the purified group-III containing source materials of claim 17.

21. A group-III nitride substrate created from the group-III nitride crystal of claim 20.

22. A device created using the group-III nitride substrate of claim 21.
